(19) United States
(12) Patent Application Publication
(10) Pub. No.: US 2025/0044349 A1
(43) Pub. Date: Feb. 6, 2025

(54) WAFER PROBE STATION AND METHOD FOR ESTABLISHING AN EVALUATION MODEL FOR CALIBRATION OF A PROBE ASSEMBLY

(71) Applicant: MPI CORPORATION, Hsinchu (TW)

(72) Inventors: ANDREJ RUMIANTSEV, Hsinchu (TW); Ching-Ling PAI, Hsinchu (TW); LIN-LIN CHIH, Hsinchu (TW)

(21) Appl. No.: 18/762,919

(22) Filed: Jul. 3, 2024

Related U.S. Application Data
(60) Provisional application No. 63/530,768, filed on Aug. 4, 2023.

(51) Int. Cl. G01R 31/28; G01R 1/073; G01R 35/00

(52) U.S. Cl. CPC G01R 31/2891; G01R 1/073; G01R 35/005

(57) ABSTRACT

To determine whether the current temperature of a probe assembly is stable for the calibration at the auxiliary site, a wafer probe station verifies a measured air standard dataset with a predetermined signal range or verifying an estimated measurement time range with a predetermined time window. To determine whether adjusting the current temperature of a probe assembly at the wafer site is necessary, a wafer probe station verifies a measured air standard dataset with a predetermined signal range or verifying an estimated measurement time range with a predetermined time window. To determine whether the current temperature of a probe assembly is ready for testing a semiconductor device, a wafer probe station verifies a measured air standard dataset with a predetermined signal range.

### CROSS-REFERENCE TO RELATED APPLICATIONS

This application claims priority to U.S. Provisional Applications No. 63/530,768 filed on Aug. 4, 2023, the entire contents of which are incorporated herein by reference.

### BACKGROUND OF THE INVENTION

The disclosure relates to a wafer probe station. More specifically, the disclosure relates to how the wafer probe station reduces error caused by temperature variation.

For some wafer probe stations, their workspace is divided into two separated sites, one of which is called “wafer site” for a process of testing a semiconductor device (i.e., Device Under Test, DUT), and the other is called “auxiliary site” for another separated process of calibrating a probe assembly, and thus, the probe assembly have to proactively or passively travel between the wafer site and the auxiliary site for different processes. Since the test process and the calibration process both are sensitive to temperature variation, and in general, the wafer site is the only one where a temperature controller for heating or cooling a temperature of the probe assembly is installed, the wafer site and the auxiliary site may be switched many times for heating or cooling the temperature of the probe assembly during the calibration process to make sure that the temperature difference of the probe assembly at the wafer site and the auxiliary site is accepted and workable for finishing the calibration process. A problem in the art is that it is hard to determine whether the current temperature of the probe assembly is stable for calibration at the auxiliary site and when the probe assembly needs to be heated or cooled at the wafer site in the calibration process. Another problem in the art is that it is hard to determine whether the current temperature of the probe assembly is ready for testing a semiconductor device as the probe assembly is being heated or cooled at the wafer site. Failure to resolve the problems will result in that the calibration result and the test result are unreliable.

### SUMMARY OF THE INVENTION

To overcomes the above-mentioned problems, the present disclosure provides a wafer probe station.

In a first embodiment of the wafer probe station, the wafer probe station may comprise a wafer site for testing a semiconductor device, and an auxiliary site for calibration. The auxiliary site is set apart from the wafer site. The wafer probe station may also comprise a probe assembly and a computer electrically connected with the probe assembly. The probe assembly may be configured to measure an air standard at the auxiliary site to provide an air standard dataset. Measuring the air standard means that the probe assembly performs a measurement in the air; that is the probe assembly performs the measurement without touching any testing circuits of a calibration substrate at the auxiliary site or any semiconductor devices of a wafer at the wafer site. The computer may be configured to verify the air standard dataset with a predetermined signal range to determine whether a temperature of the probe assembly is stable for the calibration at the auxiliary site. In addition, the probe assembly may be further configured to measure a calibration standard at the auxiliary site when the computer determines that the temperature of the probe assembly is stable for the calibration at the auxiliary site. Measuring the calibration standard means that the probe assembly performs a measurement on a calibration substrate; that is the probe assembly performs the measurement while touching a target testing circuit of a calibration substrate at the auxiliary site. In the first embodiment of the wafer probe station, the wafer probe station is able to appropriately determine whether the current temperature of the probe assembly is stable for the calibration at the auxiliary site.

In a second embodiment of the wafer probe station, the wafer probe station may comprise a wafer site for testing a semiconductor device, and an auxiliary site for calibration. The auxiliary site is set apart from the wafer site. The wafer probe station may also comprise a probe assembly and a computer electrically connected with the probe assembly. The probe assembly may be configured to measure an air standard at the auxiliary site to provide an air standard dataset before measuring a calibration standard. Measuring the air standard means that the probe assembly performs a measurement in the air; that is the probe assembly performs the measurement without touching any testing circuits of a calibration substrate at the auxiliary site or any semiconductor devices of a wafer at the wafer site. Measuring the calibration standard means that the probe assembly performs a measurement on a calibration substrate; that is the probe assembly performs the measurement while touching a target testing circuit of a calibration substrate at the auxiliary site. The computer may be configured to verify the air standard dataset with a predetermined signal range to determine whether adjusting a temperature of the probe assembly at the wafer site is necessary. The wafer probe station may also comprise a chuck moving device, and the chuck moving device may be configured to move a wafer-site chuck to the probe assembly when the computer determines that adjusting the temperature of the probe assembly at the wafer site is necessary. In the second embodiment of the wafer probe station, the wafer probe station is able to appropriately determine whether adjusting the current temperature of the probe assembly at the wafer site is necessary.

In a third embodiment of the wafer probe station, the wafer probe station may comprise a probe assembly and a computer electrically connected with the probe assembly. The probe assembly may be configured to test a semiconductor device at a wafer site and to be calibrated at an auxiliary site being set apart from the wafer site. The computer may be configured to estimate a measurement time range for the probe assembly to measure a calibration standard at the auxiliary site, and verify the measurement time range with a predetermined time window to determine whether a temperature of the probe assembly is stable for calibration at the auxiliary site. Measuring the calibration standard means that the probe assembly performs a measurement on a calibration substrate; that is the probe assembly performs the measurement while touching a target testing circuit of a calibration substrate at the auxiliary site. The computer may be further configured to record a calibration data established by measuring the calibration standard at the auxiliary site by the probe assembly in a case where the computer determines that the temperature of the probe assembly is stable for calibration at the auxiliary site. For the wafer probe station, the predetermined time window may comprise an opening time and a closing time which are defined based on a predetermined signal range. In the third embodiment of the wafer probe station, the wafer probe station is able to appropriately determine whether the current temperature of the probe assembly is stable for the calibration at the auxiliary site.

In a fourth embodiment of the wafer probe station, the wafer probe station may comprise a probe assembly, a computer electrically connected with the probe assembly. The probe assembly may be configured to test a semiconductor device at a wafer site and to be calibrated at an auxiliary site being set apart from the wafer site. The computer may be configured to estimate a measurement time range for the probe assembly to measure a calibration standard at the auxiliary site before the probe assembly measures the calibration standard, and verify the measurement time range with a predetermined time window to determine whether adjusting a temperature of the probe assembly at the wafer site is necessary. Measuring the calibration standard means that the probe assembly performs a measurement on a calibration substrate; that is the probe assembly performs the measurement while touching a target testing circuit of a calibration substrate at the auxiliary site. The wafer probe station may also comprise a chuck moving device, and the chuck moving device may be configured to move a wafer-site chuck to the probe assembly when the computer determines that adjusting the temperature of the probe assembly at the wafer site is necessary. For the wafer probe station, the predetermined time window may comprise an opening time and a closing time which are defined based on a predetermined signal range. In the fourth embodiment of the wafer probe station, the wafer probe station is able to appropriately determine whether adjusting the current temperature of the probe assembly at the wafer site is necessary.

In a fifth embodiment of the wafer probe station, the wafer probe station may comprise a wafer site for testing a semiconductor device, and an auxiliary site for calibration. The auxiliary site is set apart from the wafer site. The wafer probe station may also comprise a probe assembly and a computer electrically connected with the probe assembly. The probe assembly may be configured to measure an air standard at the wafer site to provide an air standard dataset. Measuring the air standard means that the probe assembly performs a measurement in the air; that is the probe assembly performs the measurement without touching any testing circuits of a calibration substrate at the auxiliary site or any semiconductor devices of a wafer at the wafer site. The computer may be configured to verify the air standard dataset with a predetermined signal range to determine whether a temperature of the probe assembly is ready for testing the semiconductor device at the wafer site. In the fifth embodiment of the wafer probe station, the wafer probe station is able to appropriately determine whether the current temperature of the probe assembly is ready for testing the semiconductor device.

In a sixth embodiment of the wafer probe station, the wafer probe station may comprise a probe assembly and a computer electrically connected with the probe assembly. The probe assembly may be configured to test a semiconductor device at a wafer site and to be calibrated at an auxiliary site being set apart from the wafer site. The computer may be configured to verify a time length of adjusting a temperature of the probe assembly with a predetermined time window to determine whether the temperature of the probe assembly is ready for testing the semiconductor device at the wafer site. In the sixth embodiment of the wafer probe station, the wafer probe station is able to appropriately determine whether the current temperature of the probe assembly is ready for testing the semiconductor device.

As disclosed above, the provided wafer probe station is able to appropriately determine whether the current temperature of the probe assembly is stable for the calibration at the auxiliary site, by verifying the measured air standard dataset with a predetermined signal range or verifying the estimated measurement time range with a predetermined time window. In addition, the wafer probe station is also able to appropriately determine whether adjusting the current temperature of the probe assembly at the wafer site is necessary, by verifying the measured air standard dataset with a predetermined signal range or verifying the estimated measurement time range with a predetermined time window. Moreover, the provided wafer probe station is able to appropriately determine whether the current temperature of the probe assembly is ready for testing the semiconductor device by verifying the measured air standard dataset with a predetermined signal range or verifying the time length of adjusting the temperature of the probe assembly with a predetermined time window. As a result, the provided wafer probe station can overcome the above-mentioned problems in various ways.

To overcomes the above-mentioned problems, the present disclosure also provides various methods for establishing an evaluation model for calibration of a probe assembly.

A first method for establishing an evaluation model for calibration of a probe assembly may comprise the following steps: sequentially measuring an air standard at a wafer site or at an auxiliary site by the probe assembly to establish a plurality of air standard raw datasets which correspond to a substantially same temperature; determining a signal range including an upper limit and a lower limit by a computer based on the plurality of air standard raw datasets; and establishing the evaluation model by the computer based on the signal range.

A second method for establishing an evaluation model for calibration of a probe assembly may comprise the following steps: measuring an air standard at a wafer site by the probe assembly to establish a wafer-site air standard raw dataset which corresponds to a first temperature; sequentially measuring an air standard at an auxiliary site by the probe assembly to establish a plurality of auxiliary-site air standard raw datasets which correspond to a plurality of different second temperatures respectively; determining a signal range including an upper limit and a lower limit by a computer based on a plurality of air standard raw datasets which comprise the wafer-site air standard raw dataset and the plurality of auxiliary-site air standard raw datasets; and establishing the evaluation model by the computer based on the signal range.

A third method for establishing an evaluation model for calibration of a probe assembly may comprise the following steps: sequentially measuring an air standard at a wafer site or at an auxiliary site by the probe assembly to establish a plurality of air standard raw datasets which correspond to a substantially same temperature; determining a signal range including an upper limit and a lower limit by a computer based on the plurality of air standard raw datasets; determining a time window comprising an opening time and a closing time by the computer based on the signal range; and establishing the evaluation model by the computer based on the time window.

A fourth method for establishing an evaluation model for calibration of a probe assembly may comprise the following steps: measuring an air standard at a wafer site by the probe assembly to establish a wafer-site air standard raw dataset which corresponds to a first temperature; sequentially measuring an air standard at an auxiliary site by the probe assembly to establish a plurality of auxiliary-site air standard raw datasets which correspond to a plurality of different second temperatures respectively; determining a signal range including an upper limit and a lower limit by a computer based on a plurality of air standard raw datasets which comprise the wafer-site air standard raw dataset and the plurality of auxiliary-site air standard raw datasets; determining a time window comprising an opening time and a closing time by the computer based on the signal range; and establishing the evaluation model by the computer based on the time window.

As disclosed above, the provided methods each is able to establish an appropriate evaluation model for calibration of a probe assembly. In a calibration process of the wafer probe station, one or more of the established evaluation models can be relied to determine whether the current temperature of the probe assembly is stable for the calibration at the auxiliary site and to determine whether adjusting the current temperature of the probe assembly at the wafer site is necessary. In a test process of the wafer probe station, one or more of the established evaluation models can also facilitate determining whether the current temperature of the probe assembly is ready for testing a semiconductor device as the probe assembly is heating or cooling.

The present disclosure further provides a semiconductor device tested by the above-mentioned wafer probe station.

The summary of the invention is not intended to limit the claimed invention, but merely provides basic profile of the claimed invention. The details of the claimed invention will be described with various embodiments as presented below.

### BRIEF DESCRIPTION OF DRAWINGS

FIG. 1 illustrates a schematic view of a wafer probe station according to some embodiments of the present disclosure.

FIG. 2A illustrates a schematic view of the upper limit and the lower limit of the first predetermined signal range according to some embodiments of the present disclosure.

FIG. 2B illustrates a schematic view of the upper limit and the lower limit of the first predetermined signal range according to some other embodiments of the present disclosure.

FIG. 2C illustrates a schematic view of the upper limit and the lower limit of the first predetermined signal range according to some other embodiments of the present disclosure.

FIG. 2D illustrates a schematic view of the upper limit and the lower limit of the first predetermined signal range according to some other embodiments of the present disclosure.

FIG. 3A illustrates a schematic view of the upper limit and the lower limit of the second predetermined signal range according to some embodiments of the present disclosure.

FIG. 3B illustrates a schematic view of the upper limit and the lower limit of the second predetermined signal range according to some other embodiments of the present disclosure.

FIG. 4 illustrates a schematic view of how to verify the measurement time range TR1 with a predetermined time window TW according to some embodiments of the present disclosure.

FIG. 5 illustrates a schematic view of how to verify the measurement time range TR2 with a predetermined time window TW according to some embodiments of the present disclosure.

FIG. 6 illustrates a flowchart for describing a method for establishing an evaluation model for calibration of a probe assembly according to some embodiments of the present disclosure.

FIG. 7 illustrates a flowchart for describing a method for establishing an evaluation model for calibration of a probe assembly according to some other embodiments of the present disclosure.

FIG. 8 illustrates a flowchart for describing a method for establishing an evaluation model for calibration of a probe assembly according to some other embodiments of the present disclosure.

FIG. 9 illustrates a flowchart for describing a method for establishing an evaluation model for calibration of a probe assembly according to some other embodiments of the present disclosure.

FIG. 10A and FIG. 10B together illustrates an overall workflow of a wafer probe station according to some embodiments of the present disclosure.

### DETAILED DESCRIPTION OF THE INVENTION

The embodiments as disclosed below are not intended to limit the claimed invention to any specific environment, applications, structures, processes or situations. In the attached drawings, elements which are not directly related to the claimed invention are omitted from depiction. Dimensions and dimensional relationships among individual elements in the attached drawings are only exemplary examples and are not intended to limit the claimed invention. Unless stated particularly, same element numerals may correspond to same elements in the following description without inconsistency with the claimed invention.

The terminology used herein is for the purpose of describing the embodiments only and is not intended to limit the claimed invention. The singular forms “a” and “an” are intended to include the plural forms as well, unless the context clearly indicates otherwise. The terms “comprises,” “comprising,” “includes,” “including,” etc., specify the presence of the stated features, integers, operations, elements, and/or components, but do not preclude the presence or addition of one or more other features, integers, operations, elements, components, and/or groups thereof. The term “and/or” includes any and all combinations of one or more of the associated listed items. Although the terms “first” and “second” etc., may be used herein to describe various elements, these elements should not be limited by these terms. These terms are merely used to distinguish one element from another element. Thus, for example, a first element described below could also be termed a second element, without departing from the spirit and scope of the claimed invention.

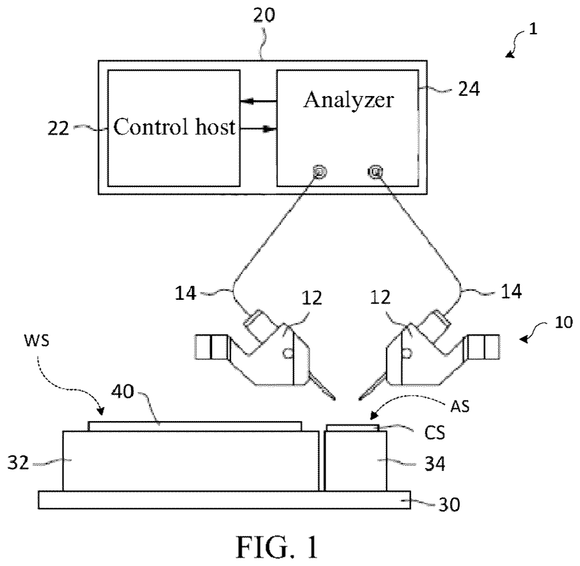

FIG. 1 illustrates, a schematic view of a wafer probe station 1 according to some embodiments of the present disclosure. The contents shown in FIG. 1 are provided only for illustrating embodiments of the present disclosure and should not be construed as any limitations on the claimed invention.

As shown in FIG. 1, the wafer probe station 1 comprises a probe assembly 10, and a computer 20 which is electrically connected with the probe assembly 10. In addition, the wafer probe station 1 comprises a workspace which is divided into a wafer site WS, and an auxiliary site AS which is set apart from the wafer site WS. The wafer site WS is arranged for testing a semiconductor device 40, while the auxiliary site AS is arranged for calibrating the probe assembly 10 with various calibration standards CS. Calibrating the probe assembly 10 with various calibration standards CS means that the probe assembly 10 measures various testing circuits configured on a calibration substrate. In one embodiment of the present disclosure, the calibration substrate can be a printed circuit board involving one or more testing circuits made of multiple metal lines so as to arrange various testing circuits of standards. The metal lines include multiple electric pads. The testing circuits include an OPEN testing circuit, a SHORT testing circuit, a LOAD testing circuit, a THROUGH testing circuit and a LINE testing circuit.

The probe assembly 10 may comprise one or more probes 12, and one or more cable 14 or other connection mediums which are used to connect the probe(s) 12 with the computer 20 in an electrical way. Further, each probe 12 may be any of various known probes or probe cards (e.g., an RF probe or a multi-contact probe), and arranged to test the semiconductor device 40 at the wafer site WS and measure various calibration substrates for calibration at the auxiliary site AS.

The Computer 20 may be implemented as a main control unit that includes a control host 22 and an analyzer 24. The control host 22 acts as a system controller that is configured to produce the data to be tested and generate control commands for operating the analyzer 24. The control host 22 can communicate with the analyzer 24 and control the analyzer 24 through signals being transmitted over a signal line (e.g., a GPIB bus). In an aspect of the present disclosure, the analyzer 24 can be implemented by a vector network analyzer (VNA) with a source measure unit (SMU). The analyzer 24 can act as a signal generation and analysis assembly that is used to transmit data, receive measured data and conduct analysis upon the measurements.

The wafer probe station 1 may also comprise a wafer-site chuck 32 set at the wafer site WS and an auxiliary-site chuck 34 set at the auxiliary site AS. The semiconductor device 40 may be placed on the wafer-site chuck 32 to be tested at the wafer site WS, while various calibration substrates may be placed on the auxiliary-site chuck 34 to be measured at the auxiliary site AS. In some embodiments, the wafer probe station 1 may further comprise a chuck moving device 30 to swap the wafer site WS for the auxiliary site AS and vice versa if the probe 12 is designed as motionless during the test process and the calibration process. On the contrary, if the probe 12 is designed as moveable, the wafer probe station 1 may comprise a probe moving device (not shown) to move the probe 12 to the wafer site WS or the auxiliary site AS from another, and thus, the wafer probe station 1 does not need the chuck moving device 30. That is to say, the probe moving device could be an electrically actuated positioning assembly, which may be configured to selectively adjust a relative orientation between the probes 12 of the probe assembly 10 and/or between the probe assembly 10 and the semiconductor device 40.

In the first embodiment of the wafer probe station 1, the wafer probe station 1 may rely on a predetermined signal range to determine whether the current temperature of the probe assembly 10 is stable for the calibration at the auxiliary site AS.

In addition, the computer 20 may be configured to verify the air standard dataset with a predetermined signal range to determine whether a temperature of the probe assembly 10 is stable for the calibration at the auxiliary site AS. When the air standard dataset falls into the predetermined signal range, the computer 20 determines that the probe assembly 10 is stable for the calibration at the auxiliary site AS. On the contrary, the computer 20 determines that the probe assembly 10 is not stable enough for the calibration at the auxiliary site AS. The probe assembly 10 may be further configured to measure a calibration standard CS at the auxiliary site AS when the computer 20 determines that the temperature of the probe assembly 10 is stable for the calibration at the auxiliary site AS. Measuring the calibration standard CS means that the probe assembly 10 performs a measurement on a calibration substrate.

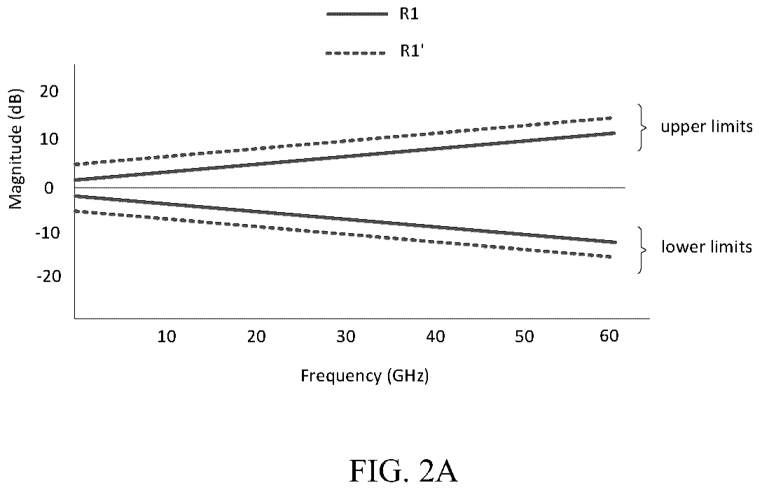

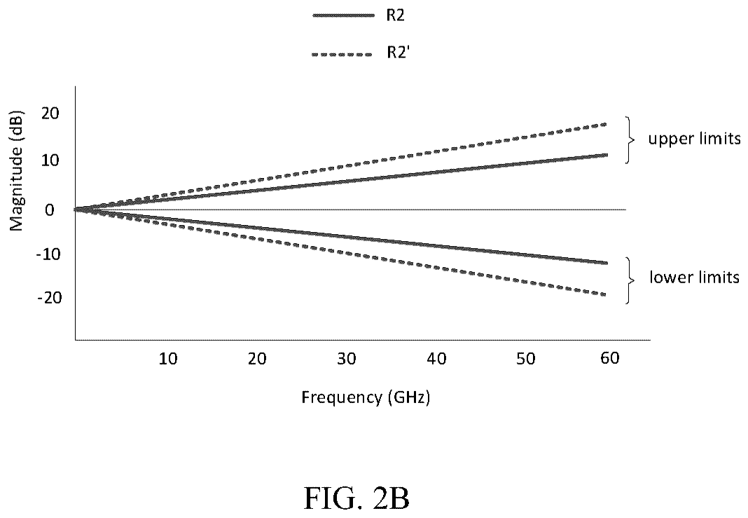

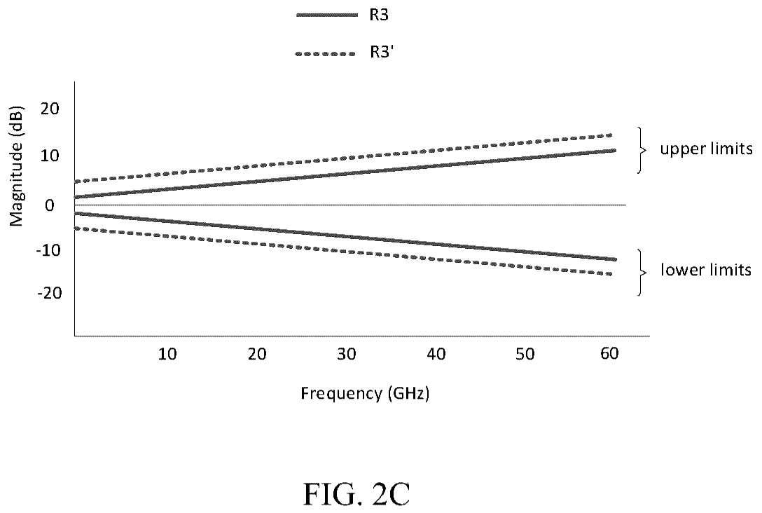

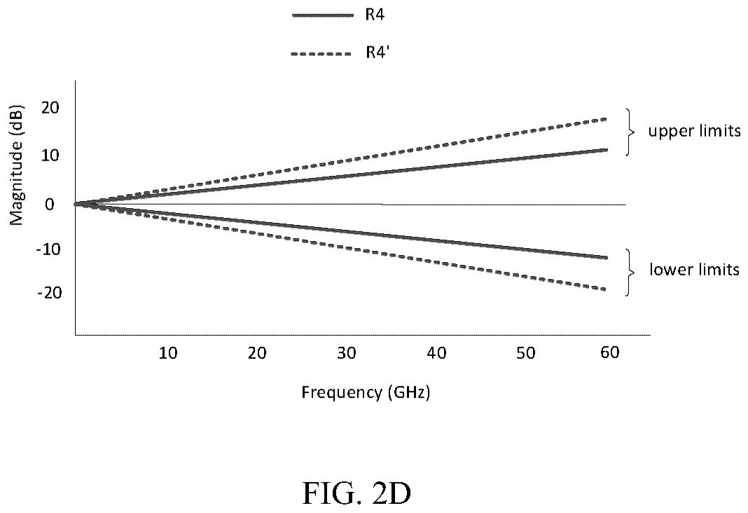

FIGS. 2A, 2B, 2C, and 2D illustrate different predetermined signal ranges for the first embodiment of the wafer probe station 1 in various situations. The contents shown in FIGS. 2A-2D are provided only for illustration and should not be construed as any limitations on the claimed invention. To clear FIGS. 2A, 2B, 2C, and 2D, the predetermined signal ranges as shown therein all are depicted in a rectilinear form instead of the actual waveforms with fluctuation.

Referring to FIG. 2A, there is an initial predetermined signal range R1 comprising an upper limit and a lower limit. The upper limit is defined by a multiplication of an adaptive coefficient and an upper-limit dataset with maximum values of a plurality of air standard raw datasets at each frequency of a bandwidth, while the lower limit is defined by a multiplication of the adaptive coefficient and a lower-limit dataset with minimum values of the plurality of air standard raw datasets at each frequency of the bandwidth. Here the plurality of air standard raw datasets correspond to a substantially same temperature. More specifically, the plurality air standard raw datasets may be established beforehand by sequentially measuring an air standard at the wafer site WS or at the auxiliary site AS by the probe assembly 10 with a natural temperature (e.g., 25° C.). The adaptive coefficient may be used to adjust the initial predetermined signal range R1 in an easier way to avoid or reduce the numbers of re-establishing a new signal range as temperature variation and/or environment variation. To this end, some experiments or simulations may be performed beforehand regarding how temperature variation and/or environment variation affects a signal range. For the Initial predetermined signal range, the adaptive coefficient R1 is set to one.

In addition, there is another predetermined signal range R1′ comprising an upper limit and a lower limit in FIG. 2A. The upper limit and the lower limit of the predetermined signal range R1′ are determined by a multiplication of an adaptive coefficient and the upper limit and the lower limit of the initial predetermined signal range R1. For example, in the case where the initial predetermined signal range R1 is established for 25° C., the adaptive coefficient may be set to 1.2 to transfer initial predetermined signal range R1 into the predetermined signal range R1′ which is applicable to 125° C.

Referring to FIG. 2B, there is an initial predetermined signal range R2 comprising an upper limit and a lower limit. The upper limit is defined by a multiplication of an adaptive coefficient and an upper-limit dataset with maximum absolute values of a plurality of air standard differential datasets at each frequency of a bandwidth, while the lower limit is defined by a multiplication of the adaptive coefficient and a lower-limit dataset with negative maximum absolute values of the plurality of air standard differential datasets at each frequency of the bandwidth. Here the plurality of air standard differential datasets correspond to a substantially same temperature. More specifically, each of the plurality of air standard differential datasets may be generated based on a difference between two air standard raw datasets established by sequentially measuring the air standard twice at the auxiliary site AS or at the wafer site WS by the probe assembly 10 with a natural temperature (e.g., 25° C.). In other words, the air standard differential datasets are generated by applying a differential calculation on every two adjacent datasets of the air standard raw datasets used for establishing the initial predetermined signal range R2. The maximum absolute value is the maximum value of the absolute values of all the differentials as calculated for each frequency, while the negative maximum absolute values is a negative value of the corresponding maximum absolute value. Since the adaptive coefficient is set to one for the Initial predetermined signal range R2, the upper limit and the lower limit of the Initial predetermined signal range R2 are actually defined by the upper-limit dataset and the lower-limit dataset respectively.

In addition, there is another predetermined signal range R2′ comprising an upper limit and a lower limit in FIG. 2B. Similar to the descriptions for FIG. 2A, the upper limit and the lower limit of the predetermined signal range R2′ may be determined by a multiplication of an adaptive coefficient and the upper limit and the lower limit of the initial predetermined signal range R2 as temperature variation and/or environment variation.

Referring to FIG. 2C, there is an initial predetermined signal range R3 comprising an upper limit and a lower limit. The upper limit is defined by a multiplication of an adaptive coefficient and an upper-limit dataset with maximum values of a plurality of air standard raw datasets at each frequency of a bandwidth, while the lower limit is defined by a multiplication of the adaptive coefficient and a lower-limit dataset with minimum values of the plurality of air standard raw datasets at each frequency of the bandwidth. The plurality of air standard raw datasets comprises a wafer-site air standard raw dataset corresponding to a first temperature and a plurality of auxiliary-site air standard raw datasets corresponding to a plurality of different second temperatures respectively. For example, the wafer-site air standard raw dataset is established by measuring an air standard at the wafer site WS at 125° C., while the auxiliary-site air standard raw datasets are established by sequentially measuring an air standard at the auxiliary site AS at 100° C., 91° C., 72° C., 50° C., etc. respectively.

In addition, there is another predetermined signal range R3′ comprising an upper limit and a lower limit in FIG. 2C. Similar to the descriptions for FIG. 2A, the upper limit and the lower limit of the predetermined signal range R3′ may be determined by a multiplication of an adaptive coefficient and the upper limit and the lower limit of the initial predetermined signal range R3 as temperature variation and/or environment variation.

Referring to FIG. 2D, there is an initial predetermined signal range R4 comprising an upper limit and a lower limit. The upper limit is defined by a multiplication of an adaptive coefficient and an upper-limit dataset with maximum absolute values of a plurality of air standard differential datasets at each frequency of a bandwidth, while the lower limit is defined by a multiplication of the adaptive coefficient and a lower-limit dataset with negative maximum absolute values of the plurality of air standard differential datasets at each frequency of the bandwidth. Here each of the plurality of air standard differential datasets is generated based on a difference between a wafer-site air standard raw dataset corresponding to a first temperature and an auxiliary-site air standard raw dataset corresponding to a second temperature. For example, the wafer-site air standard raw dataset is established by measuring an air standard at the wafer site WS at 125° C., while the auxiliary-site air standard raw datasets are established by sequentially measuring an air standard at the auxiliary site AS at 100° C., 91° C., 72° C., 50° C., etc. respectively.

In addition, there is another predetermined signal range R4′ comprising an upper limit and a lower limit in FIG. 2D. Similar to the descriptions for FIG. 2A, the upper limit and the lower limit of the predetermined signal range R4′ may be determined by a multiplication of an adaptive coefficient and the upper limit and the lower limit of the initial predetermined signal range R4 as temperature variation and/or environment variation.

In the second embodiment of the wafer probe station 1, the wafer probe station 1 may rely on a predetermined signal range to determine whether adjusting the current temperature of the probe assembly 10 at the wafer site WS is necessary. The wafer probe station 1 may determine whether adjusting the current temperature of the probe assembly 10 at the wafer site WS is necessary, in spite of that the wafer probe station 1 has determined that the current temperature of the probe assembly 10 is stable for the calibration at the auxiliary site AS. However, the process of determining whether adjusting the current temperature of the probe assembly 10 is preferably performed in the case where the probe assembly 10 has been determined to be stable. In other words, the second embodiment of the wafer probe station 1 may follow the first embodiment of the wafer probe station 1.

More specifically, in the second embodiment, the probe assembly 10 may be configured to measure an air standard at the auxiliary site AS to provide the air standard dataset every time before measuring a calibration standard CS. Measuring the air standard means that the probe assembly 10 performs a measurement in the air at the auxiliary site AS, while measuring the calibration standard CS means that the probe assembly 10 performs a measurement on a calibration substrate at the auxiliary site AS. For example, when the computer 20 has determined that the probe assembly 10 is stable, the probe assembly 10 may measure an air standard at the auxiliary site AS before measuring a calibration standard CS (e.g., a measurement on the first calibration standard CS1 for SHORT testing circuit). As another example where the probe assembly 10 has measured a calibration standard CS (e.g., a measurement on the first calibration standard CS1 for SHORT testing circuit) at the auxiliary site AS, and the computer 20 has determined that the temperature of the probe assembly 10 is still acceptable for measuring next calibration standard CS, the probe assembly 10 will be allowed to measure next calibration standard CS (e.g., a measurement on the second calibration standard CS2 for OPEN testing circuit).

In addition, The computer 20 may be configured to verify the air standard dataset with a predetermined signal range to determine whether adjusting a temperature of the probe assembly at the wafer site WS is necessary. When the air standard dataset falls into the predetermined signal range, the computer 20 determines that the temperature of the probe assembly is acceptable for measuring the calibration standard CS at the auxiliary site AS. On the contrary, the computer 20 determines that adjusting the temperature of the probe assembly at the wafer site WS is necessary. The chuck moving device 34 may be configured to move the wafer-site chuck 32 to the probe assembly 10 when the computer 20 determines that adjusting the temperature of the probe assembly 10 at the wafer site WS is necessary. Every time the probe assembly 10 completes a measurement of a calibration standard CS at the auxiliary site AS, the computer 20 may also be configured to record a calibration data.

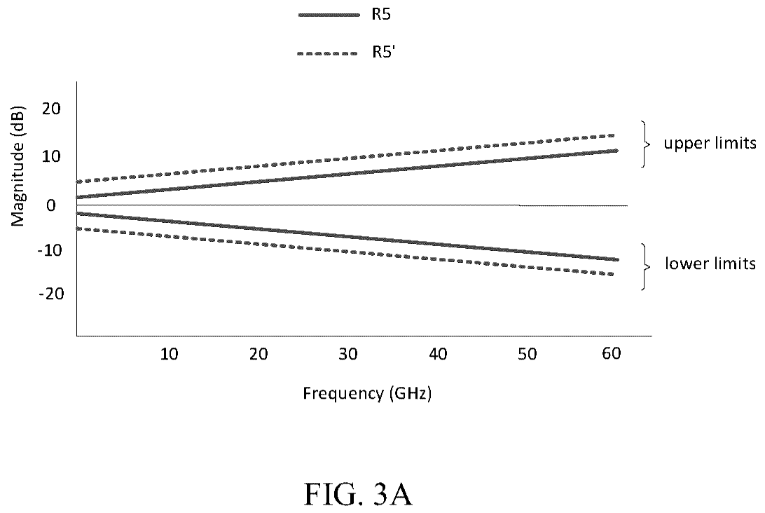

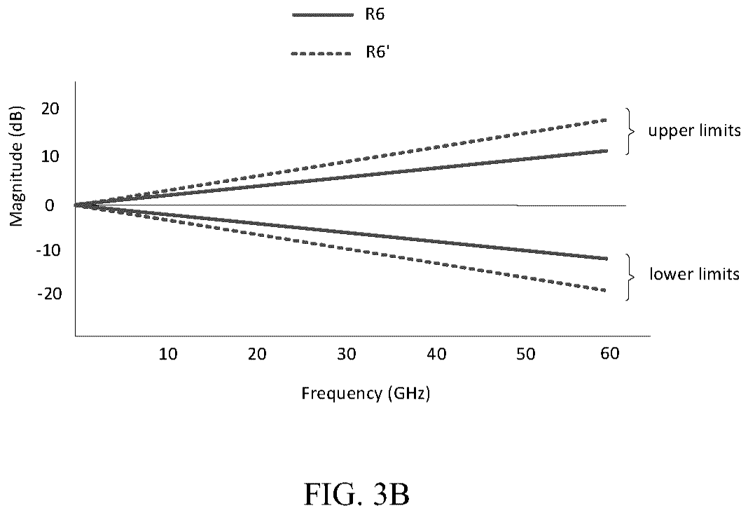

FIG. 3A and FIG. 3B illustrate different predetermined signal ranges for the second embodiment of the wafer probe station 1 in various situations. The contents shown in FIG. 3A and FIG. 3B are provided only for illustration and should not be construed as any limitations on the claimed invention. To clear FIG. 3A and FIG. 3B, the predetermined signal ranges as shown therein all are depicted in a rectilinear form instead of the actual waveforms with fluctuation.

Referring to FIG. 3A, there is an initial predetermined signal range R5 comprising an upper limit and a lower limit. The upper limit is defined by a multiplication of an adaptive coefficient and an upper-limit dataset with maximum values of a plurality of air standard raw datasets at each frequency of a bandwidth, while the lower limit is defined by a multiplication of the adaptive coefficient and a lower-limit dataset with minimum values of the plurality of air standard raw datasets at each frequency of the bandwidth. The plurality of air standard raw datasets comprising a wafer-site air standard raw dataset corresponding to a first temperature and a plurality of auxiliary-site air standard raw datasets corresponding to a plurality of different second temperatures respectively. For example, the wafer-site air standard raw dataset is established by measuring an air standard at the wafer site WS at 125° C., while the auxiliary-site air standard raw datasets are established by sequentially measuring an air standard at the auxiliary site AS at 100° C., 91° C., 72° C., 50° C., etc. respectively. The adaptive coefficient may be used to adjust the initial predetermined signal range R5 in an easier way to avoid or reduce the numbers of re-establishing a new signal range as temperature variation and/or environment variation. To this end, some experiments or simulations may be performed beforehand regarding how temperature variation and/or environment variation affects a signal range. For the Initial predetermined signal range R5, the adaptive coefficient is set to one.

In addition, there is another predetermined signal range R5′ comprising an upper limit and a lower limit in FIG. 3A. The upper limit and the lower limit of the predetermined signal range R5′ are determined by a multiplication of an adaptive coefficient and the upper limit and the lower limit of the initial predetermined signal range R5.

Referring to FIG. 3B, there is an initial predetermined signal range R6 comprising an upper limit and a lower limit. The upper limit is defined by a multiplication of an adaptive coefficient and an upper-limit dataset with maximum absolute values of a plurality of air standard differential datasets at each frequency of a bandwidth, while the lower limit is defined by a multiplication of the adaptive coefficient and a lower-limit dataset with negative maximum absolute values of the plurality of air standard differential datasets at each frequency of the bandwidth. Each of the plurality of air standard differential datasets may be generated based on a difference between a wafer-site air standard raw dataset corresponding to a first temperature and an auxiliary-site air standard raw dataset corresponding to a second temperature. The positive value means that the difference in the differential calculation is positive, while the negative value means that the difference in the differential calculation is negative. Since the adaptive coefficient is set to one for the Initial predetermined signal range R6, the upper limit and the lower limit of the Initial predetermined signal range R6 are actually defined by the upper-limit dataset and the lower-limit dataset respectively.

In addition, there is another predetermined signal range R6′ comprising an upper limit and a lower limit in FIG. 3B. Similar to the descriptions for FIG. 3A, the upper limit and the lower limit of the predetermined signal range R6′ may be determined by a multiplication of an adaptive coefficient and the upper limit and the lower limit of the initial predetermined signal range R6 as temperature variation and/or environment variation.

In the third embodiment of the wafer probe station 1, the wafer probe station 1 may rely on a predetermined time window to determine whether the current temperature of the probe assembly 10 is stable for the calibration at the auxiliary site AS. The predetermined time window comprises an opening time and a closing time which are defined based on a predetermined signal range. Specifically, the computer 20 may be configured to verify the air standard dataset with a predetermined signal range, and set the opening time and closing time based on the different results of the verification. Preferably, the opening time may refer to a time point where the temperature of the probe assembly 10 has stabilized for measuring a calibration standard CS at the auxiliary site AS, and the closing time may refer to a time point where adjusting the temperature of the probe assembly 10 at the wafer site WS is necessary. Here the predetermined signal range may be any of the predetermined signal ranges as shown in FIGS. 2A-2D, i.e., any of the predetermined signal ranges R1-R4 and R1′-R4′.

More specifically, in the third embodiment, the computer 20 may be configured to estimate a measurement time range for the probe assembly 10 to measure a calibration standard CS or to sequentially measure a plurality of calibration standards CS (e.g., the first calibration standard CS1 for SHORT testing circuit and the second calibration standard CS2 for OPEN testing circuit) at the auxiliary site AS, and verify the measurement time range with the predetermined time window to determine whether a temperature of the probe assembly 10 is stable for calibration at the auxiliary site AS. When the estimated measurement time range falls into the predetermined time window, the computer 20 determines that the temperature of the probe assembly 10 is stable for calibration at the auxiliary site AS. On the contrary, the computer 20 determines that the temperature of the probe assembly 10 is not stable enough for calibration at the auxiliary site AS. The computer 20 may also be configured to store or record a calibration data established by measuring the calibration standard CS at the auxiliary site AS by the probe assembly 10 in the case where the computer 20 determines that the temperature of the probe assembly 10 is stable for calibration at the auxiliary site AS.

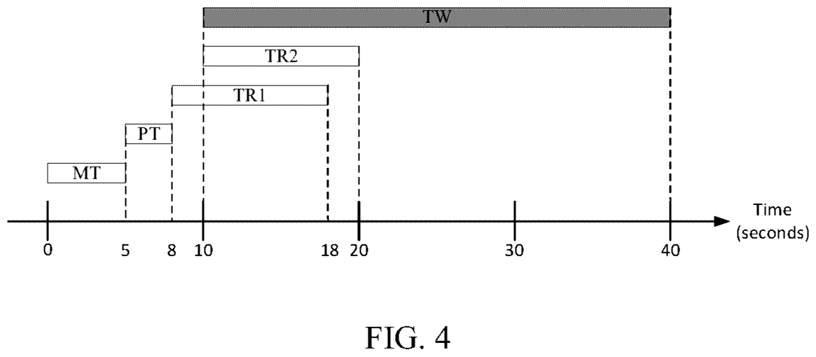

FIG. 4 illustrates how to verify a measurement time range with a predetermined time window according to the third embodiment of the wafer probe station 1. The contents shown in FIG. 4 are provided only for illustration and should not be construed as any limitations on the claimed invention.

Referring to FIG. 4, before the probe assembly 10 can be calibrated at the auxiliary site AS, there first needs a moving time MT for the chuck moving device 30 to move the auxiliary-site chuck 34 to the probe assembly 10. Then, there needs a preparation time PT for setting the probe assembly 10 and a calibration substrate for the calibration, including but limited to the Probe To Pad Alignment (PTPA) time, and the configuration time of the computer 20. For example, the moving time MT may be five (5) seconds (i.e., from the 0^{th} second to the 5^{th} second), and the subsequent preparation time PT may be three (3) seconds (i.e., from the 5^{th} second to the 8^{th} second).

For easy understanding, it is assumed that the measurement time range necessary for the probe assembly 10 to measure one or more calibration standards CS at the auxiliary site AS is 10 seconds. The first situation shows that the estimated measurement time range TR1, starting from the 8^{th} second and ending at the 18^{th} second, overlap with the predetermined time window TW, starting from the 10^{th} second and ending at the 40^{th} second. In other words, the estimated measurement time range TR1 does not completely fall into the predetermined time window TW; therefore the computer 20 may determine that the temperature of the probe assembly 10 at the 8^{th} second is not stable enough for calibration at the auxiliary site AS. However, two seconds later, the second situation shows that the estimated measurement time range TR2, starting from the 10^{th} second and ending at the 20^{th} second, falls into the predetermined time window TW, starting from the 10^{th} second and ending at the 40^{th} second; therefore the computer 20 may determine that the temperature of the probe assembly 10 at the 10^{th} second is stable enough for calibration at the auxiliary site AS. Then, the probe assembly 10 starts to measure the indicated calibration standard(s) CS at the auxiliary site AS to generate a calibration data, and the computer 20 may store or record the calibration data.

In the fourth embodiment of the wafer probe station 1, the wafer probe station 1 may rely on a predetermined time window to determine whether adjusting the current temperature of the probe assembly 10 at the wafer site WS is necessary. The process of determining whether adjusting the current temperature of the probe assembly 10 is preferably performed in the case where the probe assembly 10 has been determined to be stable. In other words, the fourth embodiment of the wafer probe station 1 may follow the first embodiment or the third embodiment of the wafer probe station 1.

Same as the third embodiment, the predetermined time window of the fourth embodiment comprises an opening time and a closing time which are defined based on a predetermined signal range. Preferably, the opening time may refer to a time point where the temperature of the probe assembly 10 has stabilized for measuring a calibration standard CS at the auxiliary site AS, and the closing time may refer to a time point where adjusting the temperature of the probe assembly 10 at the wafer site WS is necessary. Here the predetermined signal range may be any of the predetermined signal ranges as shown in FIGS. 3A-3B, i.e., any of the predetermined signal ranges R5, R5′, R6 and R6′. The predetermined time window of the fourth embodiment may be the same or different from the third embodiment.

More specifically, in the fourth embodiment, the computer 20 may be configured to estimate a measurement time range for the probe assembly 10 to measure a calibration standard CS or to sequentially measure a plurality of calibration standards CS (e.g., the first calibration standard CS1 for SHORT testing circuit and the second calibration standard CS2 for OPEN testing circuit) at the auxiliary site AS every time before the probe assembly 10 measures the calibration standard(s), and verify the measurement time range with the predetermined time window to determine whether adjusting a temperature of the probe assembly 10 at the wafer site WS is necessary. When the estimated measurement time range falls into the predetermined time window, the computer 20 determines that the current temperature of the probe assembly 10 is acceptable for measuring the calibration standard(s) CS during the estimated measurement time range and starts to measure the indicated calibration standard(s) CS at the auxiliary site AS to generate a calibration data, and the computer 20 may store or record the calibration data. On the contrary, the computer 20 determines that adjusting the current temperature of the probe assembly 10 at the wafer site WS is necessary, and the chuck moving device 30 will move the wafer-site chuck 32 to the probe assembly 10 for heating or cooling the probe assembly 10.

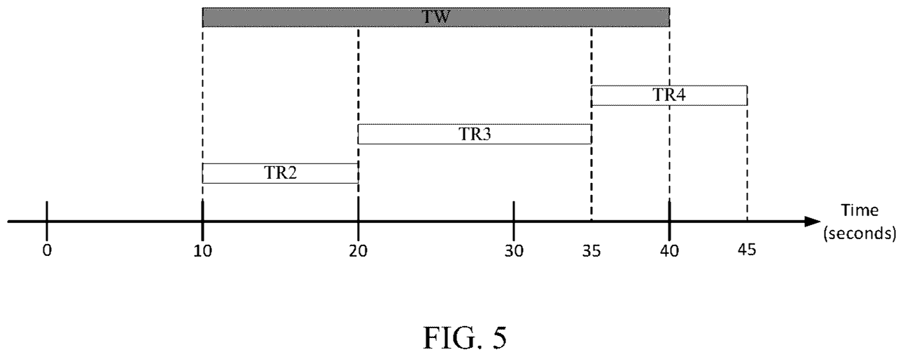

FIG. 5 illustrates how to verify a measurement time range with a predetermined time window according to the fourth embodiment of the wafer probe station 1. The contents shown in FIG. 5 are provided only for illustration and should not be construed as any limitations on the claimed invention.

Referring to FIG. 5, for easy understanding, it is assumed that the predetermined time window TW is set as 30 seconds, starting from the 10^{th} second and ending at the 40^{th} second. The first situation shows that the estimated measurement time range TR2, starting from the 10^{th} second and ending at the 20^{th} second, falls into the predetermined time window TW; therefore the computer 20 may determine that the temperature of the probe assembly 10 is acceptable for measuring the indicated calibration standard(s) CS at the auxiliary site AS during the estimated measurement time range TR2. Then, the probe assembly 10 starts to measure the indicated calibration standard(s) CS at the auxiliary site AS to generate a calibration data, and the computer 20 may store or record the calibration data. Next, The second situation shows that the estimated measurement time range TR3, starting from the 20^{th} second and ending at the 35^{th} second, still falls into the predetermined time window TW; therefore the computer 20 may determine that the residual temperature of the probe assembly 10 is still acceptable for measuring the indicated calibration standard(s) CS at the auxiliary site AS during the estimated measurement time range TR3. Then, the probe assembly 10 starts to measure the indicated calibration standard(s) CS at the auxiliary site AS to generate a calibration data, and the computer 20 may store or record the calibration data. However, the third situation shows that the estimated measurement time range TR4, starting from the 35^{th} second and ending at the 45^{th} second, overlap with the predetermined time window TW. In other words, the estimated measurement time range TR4 does not completely fall into the predetermined time window TW; therefore, the computer 20 determines that adjusting the current temperature of the probe assembly 10 at the wafer site WS is necessary, and the chuck moving device 30 will move the wafer-site chuck 32 to the probe assembly 10 for heating or cooling the probe assembly 10.

In the fifth embodiment of the wafer probe station 1, the wafer probe station 1 may rely on a predetermined signal range to determine whether the current temperature of the probe assembly 10 is ready for testing the semiconductor device 40. More specifically, the probe assembly 10 may be configured to measure an air standard at the wafer site WS to provide the air standard dataset, and the computer 20 may be configured to verify the air standard dataset with the predetermined signal range to determine whether the current temperature of the probe assembly 10 is ready for testing the semiconductor device 40 at the wafer site WS. Here the predetermined signal range may be any of the predetermined signal ranges as shown in FIGS. 2A-2B, i.e., any of the predetermined signal ranges R1-R2 and R1′-R2′.

In the sixth embodiment of the wafer probe station 1, the wafer probe station 1 may rely on a predetermined time window to determine whether the current temperature of the probe assembly 10 is ready for testing the semiconductor device 40 at the wafer site WS. Specifically, when the chuck moving device 30 moves the wafer-site chuck 32 to the probe assembly 10, the temperature of the probe assembly 10 starts to be adjusted at the wafer site WS till the temperature of the probe assembly 10 is ready for testing the semiconductor device 40 at the wafer site WS. In addition, the predetermined time window comprises an opening time and a closing time which are defined based on a predetermined signal range. Here the predetermined signal range may be any of the predetermined signal ranges as shown in FIGS. 2A-2B, i.e., any of the predetermined signal ranges R1-R2 and R1′-R2′. Preferably, the opening time may refer to a time point where the temperature of the probe assembly 10 starts to be adjusted, while the closing time may refer to a time point where the temperature of the probe assembly is ready for testing the semiconductor device at the wafer site WS. In other words, when a time range for adjusting the temperature of the probe assembly 10 at the wafer site WS is the same as the predetermined time window, the current temperature of the probe assembly 10 is ready for testing the semiconductor device 40 at the wafer site WS.

The wafer probe station 1 may utilize various evaluation models for calibration of the probe assembly 10, and thus, the present disclosure also provides various methods for establishing an evaluation model for calibration of the probe assembly 10.

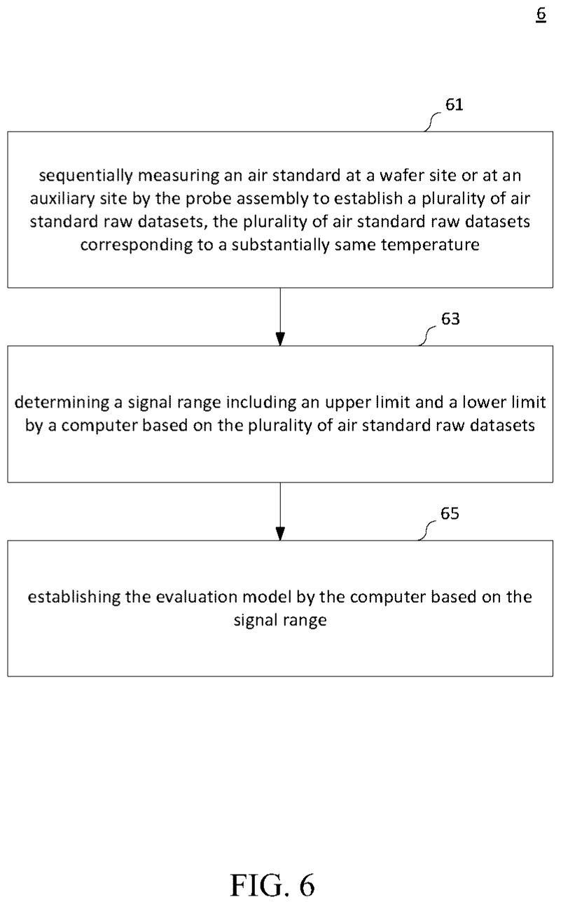

FIGS. 6, 7, 8, and 9 illustrate different methods for establishing an evaluation model for calibration of the probe assembly 10. The contents shown in FIGS. 6-9 are provided only for illustration and should not be construed as any limitations on the claimed invention.

As shown in FIG. 6, a method 6 for establishing an evaluation model (i.e., trace noise model) for calibration of a probe assembly is disclosed. The method 6 may comprise the following steps: sequentially measuring an air standard at a wafer site or at an auxiliary site by an probe assembly to establish a plurality of air standard raw datasets which correspond to a substantially same temperature (marked as “61”); determining a signal range including an upper limit and a lower limit by a computer based on the plurality of air standard raw datasets (marked as “63”); and establishing the evaluation model by the computer based on the signal range (marked as “65”).

In some embodiments of the method 6, the upper limit may be defined by a multiplication of an adaptive coefficient and an upper-limit dataset with maximum values of the plurality of air standard raw datasets at each frequency of a bandwidth, and the lower limit may be defined by a multiplication of the adaptive coefficient and a lower-limit dataset with minimum values of the plurality of air standard raw datasets at each frequency of the bandwidth. For example, here the signal range may correspond to the predetermined signal range R1 shown in FIG. 2A.

In some other embodiments of the method 6, the upper limit may be defined by a multiplication of an adaptive coefficient and an upper-limit dataset with maximum values of the plurality of air standard raw datasets at each frequency of a bandwidth, and the lower limit may be defined by a multiplication of the adaptive coefficient and a lower-limit dataset with minimum values of the plurality of air standard raw datasets at each frequency of the bandwidth. For example, here the signal range may correspond to the predetermined signal range R2 shown in FIG. 2B.

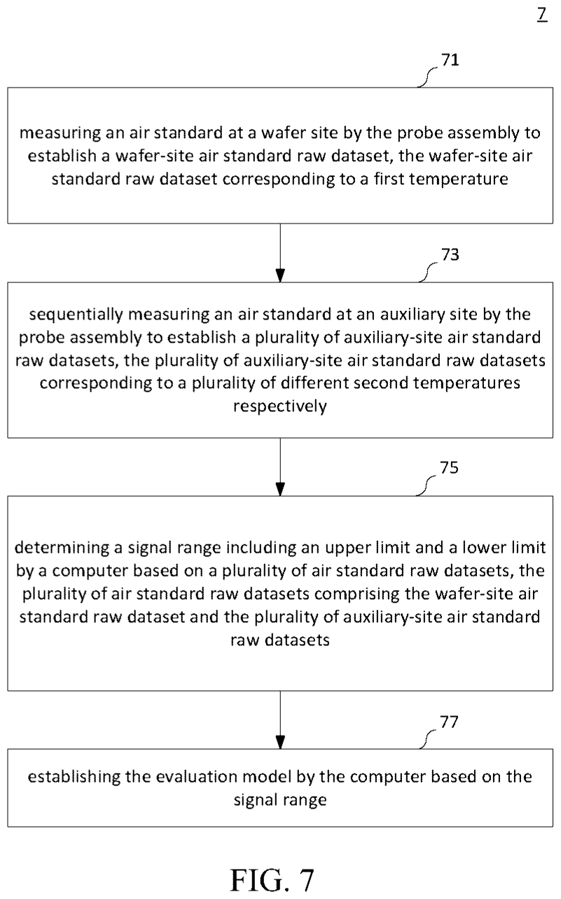

As shown in FIG. 7, a method 7 for establishing an evaluation model (i.e., temperature drift model) for calibration of a probe assembly is disclosed. The method 7 may comprise the following steps: measuring an air standard at a wafer site by the probe assembly to establish a wafer-site air standard raw dataset which corresponds to a first temperature (marked as “71”); sequentially measuring an air standard at an auxiliary site by the probe assembly to establish a plurality of auxiliary-site air standard raw datasets which correspond to a plurality of different second temperatures respectively (marked as “73”); determining a signal range including an upper limit and a lower limit by a computer based on a plurality of air standard raw datasets which comprise the wafer-site air standard raw dataset and the plurality of auxiliary-site air standard raw datasets (marked as “75”); and establishing the evaluation model by the computer based on the signal range (marked as “77”).

In some embodiments of the method 7, the upper limit is defined by a multiplication of an adaptive coefficient and an upper-limit dataset with maximum values of the plurality of air standard raw datasets at each frequency of a bandwidth and the lower limit is defined by a multiplication of the adaptive coefficient and a lower-limit dataset with minimum values of the plurality of air standard raw datasets at each frequency of the bandwidth. For example, here the signal range may correspond to the predetermined signal range R3 shown in FIG. 2C or the predetermined signal range R5 shown in FIG. 3A.

In some embodiments of the method 7, the upper limit may be defined by a multiplication of an adaptive coefficient and an upper-limit dataset with maximum absolute values of a plurality of air standard differential datasets at each frequency of a bandwidth, and the lower limit may be defined by a multiplication of the adaptive coefficient and a lower-limit dataset with negative maximum absolute values of the plurality of air standard differential datasets at each frequency of the bandwidth. In addition, each of the plurality of air standard differential datasets is generated based on a difference between the wafer-site air standard raw dataset and one of the plurality of auxiliary-site air standard raw datasets. For example, here the signal range may correspond to the predetermined signal range R4 shown in FIG. 2D or the predetermined signal range R6 shown in FIG. 3B.

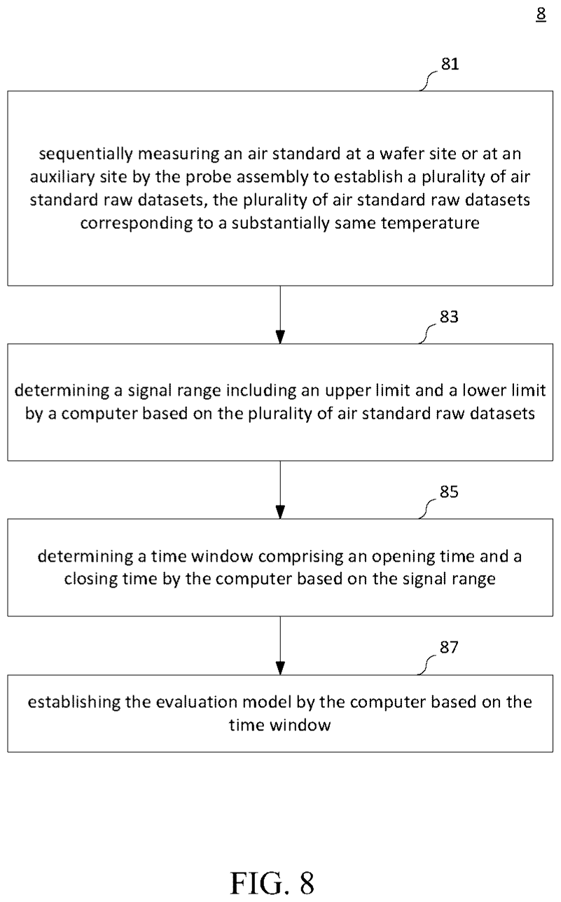

As shown in FIG. 8, a method 8 for establishing an evaluation model (i.e., time window based on trace noise model) for calibration of a probe assembly is disclosed. The method 8 may comprise the following steps: sequentially measuring an air standard at a wafer site or at an auxiliary site by the probe assembly to establish a plurality of air standard raw datasets which correspond to a substantially same temperature (marked as “81”); determining a signal range including an upper limit and a lower limit by a computer based on the plurality of air standard raw datasets (marked as “83”); determining a time window comprising an opening time and a closing time by the computer based on the signal range (marked as “85”); and establishing the evaluation model by the computer based on the time window (marked as “87”).

In some embodiments of the method 8, the upper limit may be defined by a multiplication of an adaptive coefficient and an upper-limit dataset with maximum values of the plurality of air standard raw datasets at each frequency of a bandwidth, and the lower limit may be defined by a multiplication of the adaptive coefficient and a lower-limit dataset with minimum values of the plurality of air standard raw datasets at each frequency of the bandwidth. For example, here the time window may correspond to the predetermined time window TW shown in FIG. 4 which may be determined based on the predetermined signal range R1 or R1′ shown in FIG. 2A.

In some embodiments of the method 8, the upper limit may be defined by a multiplication of an adaptive coefficient and an upper-limit dataset with maximum absolute values of a plurality of air standard differential datasets at each frequency of a bandwidth, and the lower limit may be defined by a multiplication of the adaptive coefficient and a lower-limit dataset with negative maximum absolute values of the plurality of air standard differential datasets at each frequency of the bandwidth. In addition, each of the plurality of air standard differential datasets is generated based on a difference between two adjacent datasets of the plurality of air standard raw datasets. For example, here the time window may correspond to the predetermined time window TW shown in FIG. 4 which may be determined based on the predetermined signal range R2 or R2′ shown in FIG. 2B.

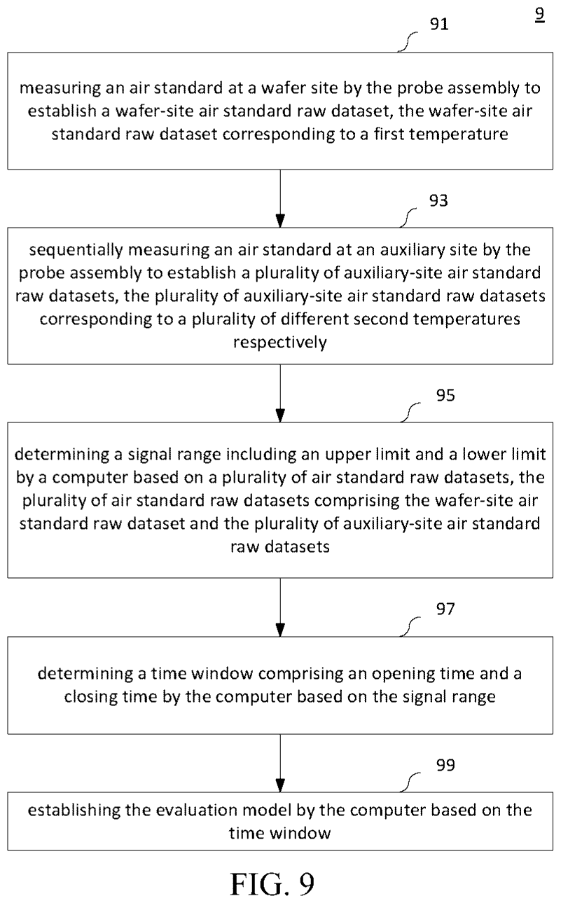

As shown in FIG. 9, a method 9 for establishing an evaluation model (i.e., time window based on temperature drift model) for calibration of a probe assembly is disclosed. The method 9 may comprise the following steps: measuring an air standard at a wafer site by the probe assembly to establish a wafer-site air standard raw dataset which corresponds to a first temperature (marked as “91”); sequentially measuring an air standard at an auxiliary site by the probe assembly to establish a plurality of auxiliary-site air standard raw datasets which correspond to a plurality of different second temperatures respectively (marked as “93”); determining a signal range including an upper limit and a lower limit by a computer based on a plurality of air standard raw datasets which comprise the wafer-site air standard raw dataset and the plurality of auxiliary-site air standard raw datasets (marked as “95”); determining a time window comprising an opening time and a closing time by the computer based on the signal range (marked as “97”); and establishing the evaluation model by the computer based on the time window (marked as “99”).

In some embodiments of the method 9, the upper limit may be defined by a multiplication of an adaptive coefficient and an upper-limit dataset with maximum values of the plurality of air standard raw datasets at each frequency of a bandwidth, and the lower limit may be defined by a multiplication of the adaptive coefficient and a lower-limit dataset with minimum values of the plurality of air standard raw datasets at each frequency of the bandwidth. For example, here the time window may correspond to the predetermined time window TW shown in FIG. 5 which may be determined based on the predetermined signal range R3 or R3′ shown in FIG. 2C or the predetermined signal range R5 or R5′ shown in FIG. 3A.

In some embodiments of the method 9, the upper limit may be defined by a multiplication of an adaptive coefficient and an upper-limit dataset with maximum absolute values of a plurality of air standard differential datasets at each frequency of a bandwidth, and the lower limit may be defined by a multiplication of the adaptive coefficient and a lower-limit dataset with negative maximum absolute values of the plurality of air standard differential datasets at each frequency of the bandwidth. In addition, each of the plurality of air standard differential datasets is generated based on a difference between the wafer-site air standard raw dataset and one of the plurality of auxiliary-site air standard raw datasets. For example, here the time window may correspond to the predetermined time window TW shown in FIG. 5 which may be determined based on the predetermined signal range R4 or R4′ shown in FIG. 2D or the predetermined signal range R6 or R6′ shown in FIG. 3B.

Each of the methods 6-9 basically corresponds to at least one certain embodiment of the wafer probe station 1. Therefore, people having ordinary skill in the art can fully understand and implement the methods 6-9 just by referring to the descriptions for the embodiments of the wafer probe station 1, even though not all of the embodiments of methods 6-9 are described in detail above.

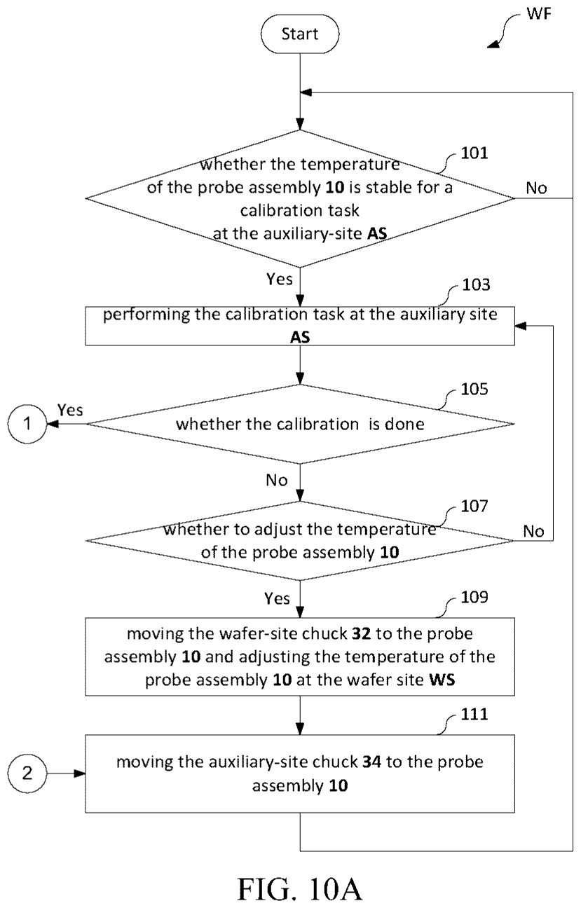

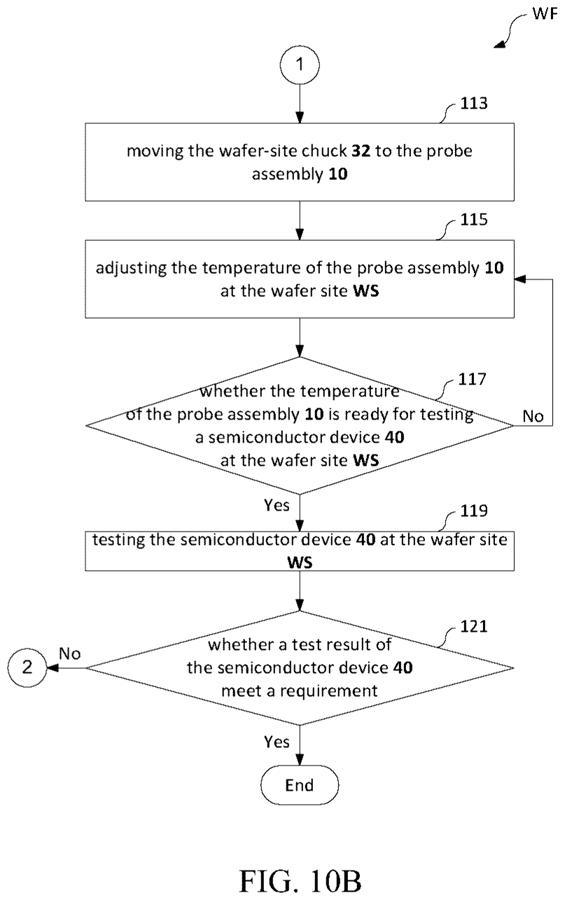

FIG. 10A and FIG. 10B together illustrates an overall workflow WF of the wafer probe station 1 according to some embodiments of the present disclosure. The contents of FIG. 10 are provided only as an example and should not be construed as any limitations on the claimed invention.

The workflow WF starts with the step 101 once the chuck moving device 30 has moved the auxiliary-site chuck 34 to the probe assembly 10 for a calibration task. In the step 101, the wafer probe station 1 determines whether a temperature of the probe assembly 10 is stable for the calibration task at the auxiliary site AS. If the determination result of the step 101 is negative, the wafer probe station 1 waits for the next determination; however, if the determination result of the step 101 is positive, the workflow WF goes to the step 103. In the step 103, the wafer probe station 1 performs the calibration task at the auxiliary site AS. The details of the step 101 and the steps 103 may refer to the first embodiment or the third embodiment of the wafer probe station 1 as mentioned above.

When the workflow WF goes to the step 105, the wafer probe station 1 determines whether the calibration task at the auxiliary-site AS is done. If the determination result of the step 105 is negative, the workflow WF goes to the step 107; however, if the determination result of the step 105 is positive, the workflow WF goes to the step 113.

In the step 107, the wafer probe station 1 determines whether to adjust the temperature of the probe assembly 10. If the determination result of the step 107 is negative, the wafer probe station 1 continues to perform the calibration task at the auxiliary site AS; however, if the determination result of the step 107 is positive, the workflow WF goes to the step 109. In the step 109, the chuck moving device 30 of the wafer probe station 1 moves the wafer-site chuck 32 to the probe assembly 10 and starts to adjust the temperature of the probe assembly 10 at the wafer site WS. The details of the step 107 and the step 109 may refer to the second embodiment or the fourth embodiment of the wafer probe station 1 as mentioned above.

The workflow WF goes to the step 111 when the temperature of the probe assembly 10 has been adjusted to a predetermined degree. In the step 111, the chuck moving device 30 moves the auxiliary-site chuck 34 to the probe assembly 10 to continue to perform the calibration task.

As mentioned above, the workflow WF goes to the step 113 when the wafer probe station 1 determines that the calibration task at the auxiliary-site AS is done. In the step 113, the chuck moving device 30 moves the wafer-site chuck 32 to the probe assembly 10 and then the workflow WF goes to the step 115. In the step 115, the wafer probe station 1 adjusts the temperature of the probe assembly 10 at the wafer site WS.

During adjusting the temperature of the probe assembly 10 at the wafer site WS, the wafer probe station 1 also determines whether the current temperature of the probe assembly 10 is ready for testing the semiconductor device 40 at the wafer site WS in the step 117. If the determination result of the step 117 is negative, the wafer probe station 1 continues to adjust the temperature of the probe assembly 10; however, if the determination result of the step 117 is positive, the workflow WF goes to the step 119. In the step 119, the wafer probe station 1 tests the semiconductor device 40 at the wafer site WS. The details of the steps 115, 117 and 119 may refer to the fifth embodiment or the sixth embodiment of the wafer probe station 1 as mentioned above.

The workflow WF goes to the step 121 when the test of the semiconductor device 40 is finished. In the step 121, the wafer probe station 1 may automatically determine whether a test result of the semiconductor device 40 meet a requirement according to a default procedure. Alternatively, users may determine whether the test result of the semiconductor device 40 meet a requirement by themselves. If the determination result of the step 121 is negative, the wafer probe station 1 will prepare another calibration task for the probe assembly 10 and the workflow WF goes to the step 111. More specifically, the probe assembly 10 may adjust the temperature of the probe assembly 10 to a predetermined degree and move the auxiliary-site chuck 34 to the probe assembly 10 for the upcoming calibration task. On the contrary, if the determination result of the step 121 is positive, the workflow WF is done. Then the wafer probe station 1 may launch another workflow for other calibration or testing processes.

Without inconsistency with the claimed invention, a variety of combinations, modifications and/or replacements of the directly or indirectly disclosed embodiments are substantially included in the whole disclosure, even though they are not especially mentioned above. The scopes of the claimed invention are defined by the following claims as appended.

What is claimed is:

1. A wafer probe station, comprising:
a probe assembly, being configured to test a semiconductor device at a wafer site and to be calibrated at an auxiliary site being set apart from the wafer site; and
a computer electrically connected with the probe assembly, being configured to:
estimate a measurement time range for the probe assembly to measure a calibration standard at the auxiliary site; and
verify the measurement time range with a predetermined time window to determine whether a temperature of the probe assembly is stable for calibration at the auxiliary site;
wherein the computer is further configured to record a calibration data established by measuring the calibration standard at the auxiliary site by the probe assembly in a case where the computer determines that the temperature of the probe assembly is stable for calibration at the auxiliary site; and
wherein the predetermined time window comprises an opening time and a closing time which are defined based on a predetermined signal range.

2. The wafer probe station of claim 1, wherein:
the predetermined signal range comprises an upper limit and a lower limit;
the upper limit is defined by a multiplication of an adaptive coefficient and an upper-limit dataset with maximum values of a plurality of air standard raw datasets at each frequency of a bandwidth, the plurality of air standard raw datasets corresponding to a substantially same temperature; and
the lower limit is defined by a multiplication of the adaptive coefficient and a lower-limit dataset with minimum values of the plurality of air standard raw datasets at each frequency of the bandwidth.

3. The wafer probe station of claim 1, wherein:
the predetermined signal range comprises an upper limit and a lower limit;
the upper limit is defined by a multiplication of an adaptive coefficient and an upper-limit dataset with maximum absolute values of a plurality of air standard differential datasets at each frequency of a bandwidth, wherein each of the plurality of air standard differential datasets is generated based on a difference between two air standard raw datasets established by sequentially measuring the air standard twice at the auxiliary site or at the wafer site, and the plurality of air standard differential datasets corresponding to a substantially same temperature; and
the lower limit is defined by a multiplication of the adaptive coefficient and a lower-limit dataset with negative maximum absolute values of the plurality of air standard differential datasets at each frequency of the bandwidth.

4. The wafer probe station of claim 1, wherein:
the predetermined signal range comprises an upper limit and a lower limit;
the upper limit is defined by a multiplication of an adaptive coefficient and an upper-limit dataset with maximum values of a plurality of air standard raw datasets at each frequency of a bandwidth, the plurality of air standard raw datasets comprising a wafer-site air standard raw dataset corresponding to a first temperature and a plurality of auxiliary-site air standard raw datasets corresponding to a plurality of different second temperatures respectively; and
the lower limit is defined by a multiplication of the adaptive coefficient and a lower-limit dataset with minimum values of the plurality of air standard raw datasets at each frequency of the bandwidth.

5. The wafer probe station of claim 1, wherein:
the predetermined signal range comprises an upper limit and a lower limit;
the upper limit is defined by a multiplication of an adaptive coefficient and an upper-limit dataset with maximum absolute values of a plurality of air standard differential datasets at each frequency of a bandwidth, each of the plurality of air standard differential datasets being generated based on a difference between a wafer-site air standard raw dataset corresponding to a first temperature and an auxiliary-site air standard raw dataset corresponding to a second temperature; and
the lower limit is defined by a multiplication of the adaptive coefficient and a lower-limit dataset with negative maximum absolute values of the plurality of air standard differential datasets at each frequency of the bandwidth.

6. The wafer probe station of claim 1, wherein the opening time refers to a time point where the temperature of the probe assembly has stabilized for measuring the calibration standard at the auxiliary site, and the closing time refers to a time point where adjusting the temperature of the probe assembly at the wafer site is necessary.

7. A wafer probe station, comprising:
a probe assembly, being configured to test a semiconductor device at a wafer site and to be calibrated at an auxiliary site being set apart from the wafer site;
a computer electrically connected with the probe assembly, being configured to:
estimate a measurement time range for the probe assembly to measure a calibration standard at the auxiliary site before the probe assembly measures the calibration standard; and
verify the measurement time range with a predetermined time window to determine whether adjusting a temperature of the probe assembly at the wafer site is necessary; and
a chuck moving device, being configured to move a wafer-site chuck to the probe assembly when the computer determines that adjusting the temperature of the probe assembly at the wafer site is necessary;
wherein the predetermined time window comprises an opening time and a closing time which are defined based on a predetermined signal range.

8. The wafer probe station of claim 7, wherein:
the predetermined signal range comprises an upper limit and a lower limit;
the upper limit is defined by a multiplication of an adaptive coefficient and an upper-limit dataset with maximum values of a plurality of air standard raw datasets at each frequency of a bandwidth, the plurality of air standard raw datasets comprising a wafer-site air standard raw dataset corresponding to a first temperature and a plurality of auxiliary-site air standard raw datasets corresponding to a plurality of different second temperatures respectively; and
the lower limit is defined by a multiplication of the adaptive coefficient and a lower-limit dataset with minimum values of the plurality of air standard raw datasets at each frequency of the bandwidth.

9. The wafer probe station of claim 7, wherein:
the predetermined signal range comprises an upper limit and a lower limit;
the upper limit is defined by a multiplication of an adaptive coefficient and an upper-limit dataset with maximum absolute values of a plurality of air standard differential datasets at each frequency of a bandwidth, each of the plurality of air standard differential datasets being generated based on a difference between a wafer-site air standard raw dataset corresponding to a first temperature and an auxiliary-site air standard raw dataset corresponding to a second temperature; and
the lower limit is defined by a multiplication of the adaptive coefficient and a lower-limit dataset with negative maximum absolute values of the plurality of air standard differential datasets at each frequency of the bandwidth.

10. The wafer probe station of claim 7, wherein the opening time refers to a time point where the temperature of the probe assembly has stabilized for measuring the calibration standard at the auxiliary site, and the closing time refers to a time point where adjusting the temperature of the probe assembly at the wafer site is necessary.

11. A wafer probe station, comprising:
a probe assembly, being configured to test a semiconductor device at a wafer site and to be calibrated at an auxiliary site being set apart from the wafer site; and
a computer electrically connected with the probe assembly, being configured to verify a time length of adjusting a temperature of the probe assembly with a predetermined time window to determine whether the temperature of the probe assembly is ready for testing the semiconductor device at the wafer site;
wherein the predetermined time window comprises an opening time and a closing time which are defined based on a predetermined signal range.

12. The wafer probe station of claim 11, wherein:
the predetermined signal range comprises an upper limit and a lower limit;
the upper limit is defined by a multiplication of an adaptive coefficient and an upper-limit dataset with maximum values of a plurality of air standard raw datasets at each frequency of a bandwidth, the plurality of air standard raw datasets corresponding to a substantially same temperature; and
the lower limit is defined by a multiplication of the adaptive coefficient and a lower-limit dataset with minimum values of the plurality of air standard raw datasets at each frequency of the bandwidth.

13. The wafer probe station of claim 11, wherein:
the predetermined signal range comprises an upper limit and a lower limit;
the upper limit is defined by a multiplication of an adaptive coefficient and an upper-limit dataset with maximum absolute values of a plurality of air standard differential datasets at each frequency of a bandwidth, wherein each of the plurality of air standard differential datasets is generated based on a difference between two air standard raw datasets established by sequentially measuring the air standard twice at the auxiliary site or at the wafer site, and the plurality of air standard differential datasets corresponding to a substantially same temperature; and
the lower limit is defined by a multiplication of the adaptive coefficient and a lower-limit dataset with negative maximum absolute values of the plurality of air standard differential datasets at each frequency of the bandwidth.

14. The wafer probe station of claim 11, wherein:
the opening time refers to a time point where the temperature of the probe assembly starts to be adjusted, and the closing time refers to a time point where the temperature of the probe assembly is ready for testing the semiconductor device at the wafer site.

15. A method for establishing an evaluation model for calibration of a probe assembly, comprising:
sequentially measuring an air standard at a wafer site or at an auxiliary site by the probe assembly to establish a plurality of air standard raw datasets, the plurality of air standard raw datasets corresponding to a substantially same temperature;
determining a signal range including an upper limit and a lower limit by a computer based on the plurality of air standard raw datasets;
determining a time window comprising an opening time and a closing time by the computer based on the signal range; and
establishing the evaluation model by the computer based on the time window.

16. The method of claim 15, wherein:
the upper limit is defined by a multiplication of an adaptive coefficient and an upper-limit dataset with maximum values of the plurality of air standard raw datasets at each frequency of a bandwidth; and
the lower limit is defined by a multiplication of the adaptive coefficient and a lower-limit dataset with minimum values of the plurality of air standard raw datasets at each frequency of the bandwidth.

17. The method of claim 15, wherein:
the upper limit is defined by a multiplication of an adaptive coefficient and an upper-limit dataset with maximum absolute values of a plurality of air standard differential datasets at each frequency of a bandwidth, wherein each of the plurality of air standard differential datasets is generated based on a difference between two adjacent datasets of the plurality of air standard raw datasets; and
the lower limit is defined by a multiplication of the adaptive coefficient and a lower-limit dataset with negative maximum absolute values of the plurality of air standard differential datasets at each frequency of the bandwidth.

18. The method of claim 15, wherein the opening time refers to a time point where a temperature of the probe assembly has stabilized for measuring a calibration standard at the auxiliary site, and the closing time refers to a time point where adjusting the temperature of the probe assembly at the wafer site is necessary.

19. A method for establishing an evaluation model for calibration of a probe assembly, comprising:
measuring an air standard at a wafer site by the probe assembly to establish a wafer-site air standard raw dataset, the wafer-site air standard raw dataset corresponding to a first temperature;
sequentially measuring an air standard at an auxiliary site by the probe assembly to establish a plurality of auxiliary-site air standard raw datasets, the plurality of auxiliary-site air standard raw datasets corresponding to a plurality of different second temperatures respectively;
determining a signal range including an upper limit and a lower limit by a computer based on a plurality of air standard raw datasets, the plurality of air standard raw datasets comprising the wafer-site air standard raw dataset and the plurality of auxiliary-site air standard raw datasets;
determining a time window comprising an opening time and a closing time by the computer based on the signal range; and
establishing the evaluation model by the computer based on the time window.

20. The method of claim 19, wherein:
the upper limit is defined by a multiplication of an adaptive coefficient and an upper-limit dataset with maximum values of the plurality of air standard raw datasets at each frequency of a bandwidth; and
the lower limit is defined by a multiplication of the adaptive coefficient and a lower-limit dataset with minimum values of the plurality of air standard raw datasets at each frequency of the bandwidth.

21. The method of claim 19, wherein:
the upper limit is defined by a multiplication of an adaptive coefficient and an upper-limit dataset with maximum absolute values of a plurality of air standard differential datasets at each frequency of a bandwidth, each of the plurality of air standard differential datasets being generated based on a difference between the wafer-site air standard raw dataset and one of the plurality of auxiliary-site air standard raw datasets; and
the lower limit is defined by a multiplication of the adaptive coefficient and a lower-limit dataset with negative maximum absolute values of the plurality of air standard differential datasets at each frequency of the bandwidth.

22. The method of claim 19, wherein the opening time refers to a time point where a temperature of the probe assembly has stabilized for measuring a calibration standard at the auxiliary site, and the closing time refers to a time point where adjusting the temperature of the probe assembly at the wafer site is necessary.

23. A semiconductor device tested by a wafer probe station of claim 11.
